(19) United States
(12) Patent Application Publication
(10) Pub. No.: US 2008/0079098 A1
(43) Pub. Date: Apr. 3, 2008

(54) Semiconductor Device and Fabricating Method Thereof

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/857,777

(22) Filed: Sep. 19, 2007

(30) Foreign Application Priority Data
Sep. 28, 2006 (KR) 10-2006-0094645

(51) Int. Cl. H01L 29/94; H01L 21/336

(52) U.S. Cl. 257/412; 438/197; 257/E21.409; 257/E29.345

(57) ABSTRACT

Provided are a semiconductor device and a fabricating method thereof. In the method, a first wafer including a core region is fabricated. A second wafer including an input/output region is fabricated. Subsequently, the first wafer is coupled to the second wafer. Since an embodiment does not require a process for controlling the thicknesses of oxide layers of the core and I/O regions, manufacturing costs can be reduced.

### CROSS-REFERENCE TO RELATED APPLICATION

The present application claims the benefit under 35 U.S.C. §119 of Korean Patent Application No. 10-2006-0094645, filed Sep. 28, 2006, which is hereby incorporated by reference in its entirety.

### BACKGROUND

A semiconductor device is roughly divided into a core region and an input/output (I/O) region. The core region requires a high integration degree of the device. Accordingly, a more precise design rule is generally applied to the core region as compared with other regions within the device according to requirement for a high integration degree.

On the other hand, the I/O region of the semiconductor device is a region to which an operating voltage of the device is applied. In an aspect of a design rule, an I/O region process requires a lower precision than a precision required by a core region process. For example, a low voltage transistor of a core region used for a 90 nm foundry compatible technology (FCT) process uses an operating voltage of 1.0 V, which is lower than 1.5 or 1.2 V required by a related art 0.13 μm technology node, and requires a high integration degree. Therefore, the size of the transistor reduces, and the low voltage transistor requires a design rule of a higher precision level than a precision level of the related art technology node. However, an operating voltage of 3.3 V or 2.5 V, which has been used for the technology node is still used in an I/O region during the 90 nm FCT process. In fabricating a transistor, an I/O region process does not require the precise design rule or process technology required by a core region process. That is, a semiconductor device of one generation advanced technology node requires more precise process technology or process equipment in a core region, but does not require the precise process technology or process equipment that has been required by the core region in an I/O region. The I/O region can be sufficiently realized using related art process technology and equipment that have been used for the related art technology node.

However, as illustrated in FIG. 1, since a core region and an I/O region are finally realized while the same process is performed in the same wafer in a related art method for fabricating a semiconductor device, manufacturing costs of the I/O region increase unnecessarily.

Also, since a separate mask process is required for forming a core region and an I/O region, the related art method is inefficient in an aspect of a manufacturing time or costs.

### BRIEF SUMMARY

Accordingly, embodiments of the present invention provide a semiconductor device and fabricating method thereof. In one embodiment of a method for fabricating a semiconductor device, the method includes: fabricating a first wafer including a core region; fabricating a second wafer including an input/output region; and coupling the core region of the first wafer to the input/output region of the second wafer.

A semiconductor device according to an embodiment of the present invention includes: a first wafer including a core region; a second wafer including an input/output region; and connection electrodes for connecting the first wafer with the second wafer.

The details of one or more embodiments are set forth in the accompanying drawings and the description below. Other features will be apparent from the description and drawings, and from the claims.

### BRIEF DESCRIPTION OF THE DRAWINGS

FIG. 1 is a conceptual view illustrating a related art method for fabricating a semiconductor device.

FIG. 2 is a conceptual view illustrating a method for fabricating a semiconductor device according to an embodiment of the present invention.

FIG. 3 is a conceptual view illustrating a semiconductor device according to an embodiment of the present invention.

FIG. 4A is a cross-sectional view illustrating a core region of a semiconductor device according to an embodiment of the present invention.

FIG. 4B is a cross-sectional view illustrating an I/O region of a semiconductor device according to an embodiment of the present invention.

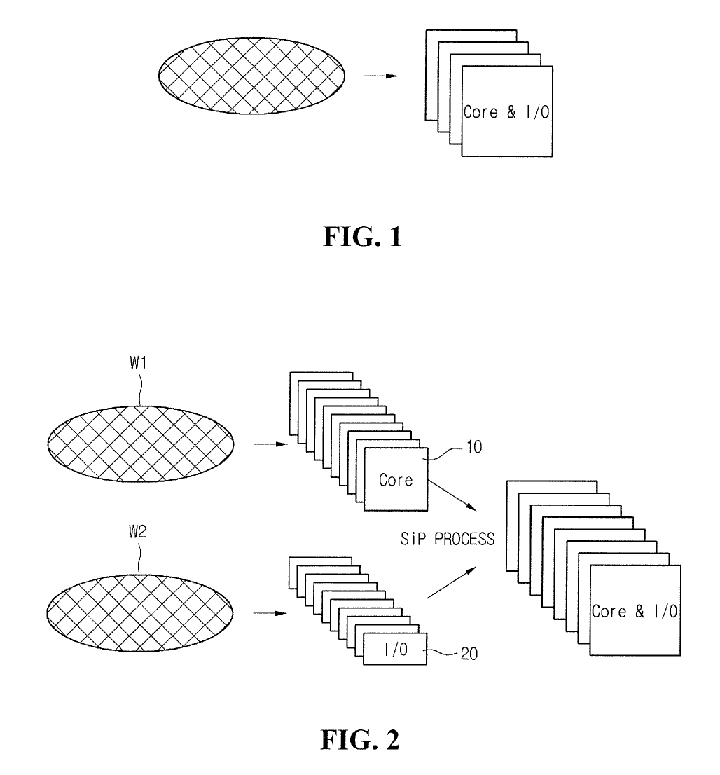

### DETAILED DESCRIPTION

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

Hereinafter, an embodiment is described in detail with reference to the accompanying drawings. It should be noted that like reference numerals refer to like elements throughout the specification. In description of embodiments, detailed descriptions of known functions or structures are omitted not to obscure the spirit of the embodiments.

Referring to FIG. 2, a first wafer W1 and a second wafer W2 can be separately prepared. A core region 10 can be formed in the first wafer W1. An I/O region 20 can be formed in the second wafer W2 simultaneously with using a parallel process, before, or after the forming of the core region 10 in the first wafer W1.

Table 1 shows an example for forming the first wafer W1 and the second wafer W2, and provides an operating voltage and a minimum channel length for each core region and each I/O region of a FCT generic logic device.

TABLE 1

| | Region | | | | | | | | |
|---|---|---|---|---|---|---|---|---|---|
| | CORE (low voltage | | | | | | | | |
| Technology | area) | | | I/O (High voltage area) | | | | | |
| node | 0.18 μm | 0.13 μm | 90 nm | 0.18 μm | 0.13 μm | | 90 nm | | |
| Operating | 1.8 | 1.2 | 1.0 | 3.3 | 3.3 | 2.5 | 3.3 | 2.5 | 1.8 |
| voltage (V) | | | | | | | | | |
| Channel | 160 | 110 | 60 | 330 | 330 | 260 | 330 | 260 | 150 |
| length(nm) | | | | | | | | | |
| for NMOS | | | | | | | | | |

As revealed in Table 1, since an I/O region does not require a precise design rule unlike a core region, most of a process for forming an I/O region does not require a precise process technology and equipment of a level required by a process for forming a core region.

For example, gate patterning of the core region uses a precise ArF lithography process technology, but less precise KrF lithography process technology can be sufficiently applied for the I/O region.

That is, in the case where the technology node is 0.13 μm, an operating voltage is 1.2 V and a channel length is formed to 110 nm during a process for forming the core region, but an operating voltage is 3.3 V for a channel length of 330 nm, and an operating voltage is 2.5 V for a channel length of 260 nm during a process for forming the I/O region. Therefore, process technology for forming the I/O region can sufficiently fabricate a semiconductor device of a desired level even when the technology is less precise compared to process technology for forming a core region.

As descried above, an operating voltage upon manufacturing of the first wafer is made lower than an operating voltage upon manufacturing of the second wafer when the first and second wafers are manufactured. Also, the operating voltage upon the manufacturing of the fist wafer may be 1.0 to 1.8 V, and the operating voltage upon manufacturing of the second wafer may be 1.8 to 3.3 V when the first and second wafers are manufactured.

Of course, it is apparent from Table 1 that an operating voltage can change and the operating voltage can change in a predetermined range depending on a channel length as a factor for forming the core and I/O regions in the first and second wafers W1 and W2.

After fabricating the first and second wafers W1 and W2, chips from the first and second wafers W1 and W2 are coupled to each other.

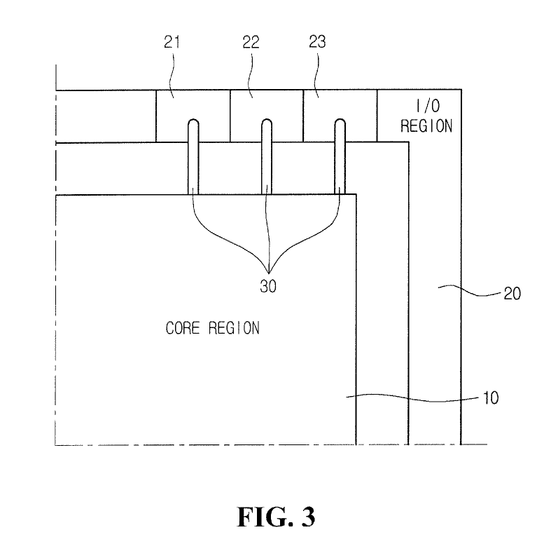

The coupling of the first and second wafers W1 and W2 can be performed using a process known as system in package (SiP). FIG. 3 is a conceptual view illustrating a semiconductor device according to an embodiment, and particularly illustrating the semiconductor device where a connection electrode is formed in the SiP process. The core region 10 and the I/O region 20 can be disposed to face each other, and connection electrodes 30 can be formed using a general wiring process to electrically connect and couple a chip from the first wafer including the core region to a chip from the second wafer including the I/O region.

The connection electrodes 30 couple the core region 10 to I/O cells 21, 22, and 23 of the I/O region.

Though the first and second wafers are electrically connected and coupled to each other using the connection electrodes in the present disclosure, it would be obvious to those having an ordinary skill in the art that wafers including various devices manufactured by applying different design rules can be connected to each other using all means that makes electrical connection possible.

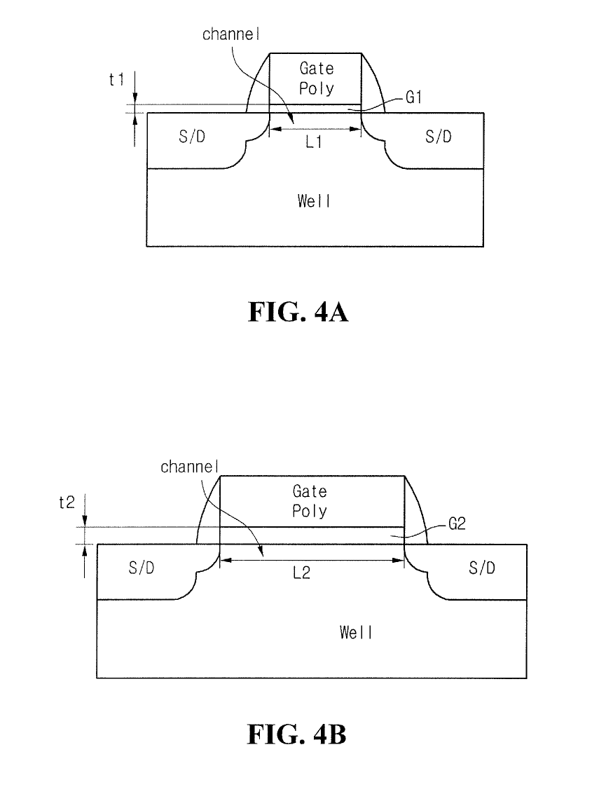

FIG. 4A is a cross-sectional view illustrating a transistor for a core region, and FIG. 4B is a cross-sectional view illustrating a transistor for an I/O region. FIGS. 4A and 4B illustrate a difference between the core region and the I/O region. Referring to FIGS. 4A and 4B, source/drain (S/D) regions are formed in a semiconductor substrate around a gate poly (gate electrode). A gate oxide layer G1 is formed between the gate poly and the semiconductor substrate in the core region. The I/O region has the same structure as that of the core region, but the widths of the gate poly (gate electrode or line) and a gate oxide layer G2 are formed wider than those of the core region.

Also, the thickness T1 of the gate oxide layer G1 in the core region is thinner than the thickness T2 of the gate oxide layer G2 in the I/O region. The channel length L1 of the core region is shorter than the channel length L2 of the I/O region. Therefore, in the case where the core region and the I/O region are formed simultaneously in the same wafer, a mask process and an etching process are required for controlling the thicknesses of the gate oxide layers of the core and I/O regions.

In contrast, in the method for fabricating the semiconductor device according to an embodiment, the core region 10 and the I/O region 20 are formed in a pair of wafers W1 and W2, respectively, and the wafers W1 and W2 are connected and coupled to each other using an electrical connecting means such as the connection electrodes 30. Accordingly, a mask process and an etching process do not need to be performed for controlling the thicknesses of the gate oxide layers of the core and I/O regions, which remarkably reduces manufacturing time and manufacturing costs.

Although a method for fabricating the semiconductor device has been described with reference to the accompanying drawings, the embodiments are not limited to the embodiment and drawings disclosed in the present specification, and various modifications can be made by those having an ordinary skill in the art within the scope and sprit of the embodiments.

In the method for fabricating the semiconductor device according to an embodiment of the present invention, the core region and the I/O region for a semiconductor device are formed in a pair of wafers, respectively, and a chip from each of the wafers are connected and coupled to each other using an electrical connecting means such as connection electrodes. Accordingly, a mask process and an etching process do not need to be performed for controlling the thicknesses of the gate oxide layers of the core and I/O regions, which remarkably reduces manufacturing time and manufacturing costs.

What is claimed is:

1. A method for fabricating a semiconductor device, the method comprising:
fabricating a first wafer including a core region;
fabricating a second wafer including an input/output region; and
coupling the core region of the first wafer to the input/output region of the second wafer.

2. The method according to claim 1, wherein coupling the core region of the first wafer to the input/output region of the second wafer comprises using connection electrodes.

3. The method according to claim 1, wherein an operating voltage for the first wafer is lower than an operating voltage for the second wafer.

4. The method according to claim 3, wherein the operating voltage for the first wafer is 1.0 to 1.5 volts, and the operating voltage for the second wafer is 1.8, 2.5, or 3.3 volts.

5. The method according to claim 1, wherein fabricating the first wafer including the core region comprises using an ArF lithography process.

6. The method according to claim 1, wherein fabricating the second wafer including the input/output region comprises using a KrF lithography process.

7. A semiconductor device comprising:
a core region from a first wafer;
an input/output region from a second wafer; and
connection electrodes connecting the core region from the first wafer with the input/output region from the second wafer.

8. The semiconductor device according to claim 7, wherein the core region comprises a first gate poly, first source/drain regions, and a first gate oxide layer; and wherein the input/output region comprises a second gate poly, second source/drain regions, and a second gate oxide layer.

9. The semiconductor device according to claim 8, wherein the thickness of the first gate oxide layer in the core region is different from the thickness of the second gate oxide layer in the input/output region.

10. The semiconductor device according to claim 8, wherein the channel length of the core region is different from the channel length of the input/output region.
